(19) United States
(12) Patent Application Publication
(10) Pub. No.: US 2024/0387589 A1
(43) Pub. Date: Nov. 21, 2024

(54) IMAGE SENSOR AND METHOD FOR FABRICATING THE SAME

(71) Applicant: Samsung Electronics Co., Ltd., Suwon-si (KR)

(72) Inventors: Ji Eun KIM, Suwon-si (KR); Soon-Im BAE, Suwon-si (KR); Woo Jae KANG, Suwon-si (KR); Keo-Sung PARK, Suwon-si (KR); Hak Jin LEE, Suwon-si (KR)

(21) Appl. No.: 18/430,367

(22) Filed: Feb. 1, 2024

(30) Foreign Application Priority Data
May 19, 2023 (KR) 10-2023-0064858

(51) Int. Cl. H01L 27/146

(52) U.S. Cl. CPC H01L 27/14636; H01L 27/14621; H01L 27/14627; H01L 27/14685

(57) ABSTRACT

There is provided an image sensor in which a leakage current caused by an anti-reflection layer is attenuated. The image sensor includes a first region and a second region in the periphery of the first region, the image sensor including a substrate including a light-receiving surface on which light is incident, a photoelectric conversion region in the substrate within the first region, a first anti-reflection layer extended along the light-receiving surface within the first region, the first anti-reflection layer including a conductive material layer, a second anti-reflection layer extended along the light-receiving surface within the second region, the second anti-reflection layer not including the conductive material layer, and a conductive pattern, at least a portion of the conductive pattern is disposed on the second anti-reflection layer and a second portion of the conductive pattern passes through the second anti-reflection layer.

### CROSS-REFERENCE TO RELATED APPLICATION

This application claims priority from Korean Patent Application No. 10-2023-0064858 filed on May 19, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to an image sensor and a method for fabricating the same, and more particularly, to an image sensor including an anti-reflection layer and a method for fabricating the same.

### Description of the Related Art

An image sensor is a semiconductor element that converts optical information into an electrical signal. The image sensor may include a charge coupled device (CCD) image sensor and a complementary metal-oxide semiconductor (CMOS) image sensor.

The image sensor may be configured in the form of package, and at this time, the package may be configured in a structure that protects the image sensor and at the same time allows light to be incident on a photo receiving surface or a sensing area of the image sensor.

### BRIEF SUMMARY

An object of the present disclosure is to provide an image sensor in which a leakage current caused by an anti-reflection layer is attenuated.

Another object of the present disclosure is to provide a method for fabricating an image sensor in which a leakage current caused by an anti-reflection layer is attenuated.

The objects of the present disclosure are not limited to those mentioned above, and additional objects of the present disclosure, which are not mentioned herein, will be clearly understood by those skilled in the art from the following description of the present disclosure.

According to an aspect of the present disclosure, there is provided an image sensor including a first region and a second region in the periphery of the first region, the image sensor comprising a substrate including a light-receiving surface on which light is incident, a photoelectric conversion region in the substrate within the first region, a first anti-reflection layer extended along the light-receiving surface within the first region, the first anti-reflection layer including a conductive material layer, a second anti-reflection layer extended along the light-receiving surface with the second region, the second anti-reflection layer not including the conductive material layer, and a conductive pattern within the second region, wherein at least a first portion of the conductive pattern is disposed on the second anti-reflection layer and a second portion of the conductive pattern passes through the second anti-reflection layer.

According to another aspect of the present disclosure, there is provided an image sensor including a first region and a second region in the periphery of the first region, the image sensor comprising a substrate, a photoelectric conversion region in the substrate within the first region, a first anti-reflection layer including a first insulating material layer, a conductive material layer and a second insulating material layer, which are sequentially stacked on the substrate within the first region, a second anti-reflection layer, which includes the first insulating material layer and the second insulating material layer that is in contact with the first insulating material layer, on the substrate within the second region, and a conductive pattern within the second region, wherein at least a first portion of the conductive pattern is disposed on the second anti-reflection layer and a second portion of the conductive pattern passes through the second anti-reflection layer.

According to still another aspect of the present disclosure, there is provided an image sensor including a first region and a second region in the periphery of the first region, the image sensor comprising a first substrate including a first surface and a second surface, which are opposite to each other, a photoelectric conversion region in the first substrate within the first region, a first circuit element on the first surface of the first substrate, a first wiring structure, which is electrically connected to the first circuit element, on the first surface of the first substrate, a first anti-reflection layer, which includes at least one insulating material layer and at least one conductive material layer, on the second surface of the first substrate within the first region, a second anti-reflection layer, which includes the at least one insulating material layer and does not include the at least one conductive material layer, on the second surface of the first substrate within the second region, a conductive pattern within the second region, at least a first portion of the conductive pattern is disposed on the second anti-reflection layer and a second portion of the conductive pattern passes through the second anti-reflection layer, a second substrate including a third surface facing the first surface of the first substrate and a fourth surface opposite to the third surface, a second circuit element on the third surface of the second substrate, and a second wiring structure, which is electrically connected to the second circuit element, on the third surface of the second substrate.

### BRIEF DESCRIPTION OF THE DRAWINGS

The above and other aspects and features of the present disclosure will become more apparent by describing in detail example embodiments thereof with reference to the attached drawings, in which:

FIG. 1 is an example block diagram illustrating an image sensor according to some embodiments;

FIG. 2 is an example circuit diagram illustrating an image sensor according to some embodiments;

FIG. 3 is an example layout view illustrating an image sensor according to some embodiments;

FIG. 4 is a schematic cross-sectional view illustrating an image sensor according to some embodiments;

FIGS. 5 and 6 are various enlarged views illustrating a region R1 and a region R2 of FIG. 4, respectively.

FIG. 7 is a schematic cross-sectional view illustrating an image sensor according to some embodiments;

FIGS. 8 and 9 are various enlarged views illustrating a region R1 and a region R2 of FIG. 7, respectively;

FIGS. 10 to 13 are various schematic cross-sectional views illustrating an image sensor according to some embodiments;

FIGS. 14 to 22 are views illustrating intermediate steps to describe a method for fabricating an image sensor according to some embodiments;

FIGS. 23 and 24 are views illustrating intermediate steps to describe a method for fabricating an image sensor according to some embodiments.

### DETAILED DESCRIPTION OF THE DISCLOSURE

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

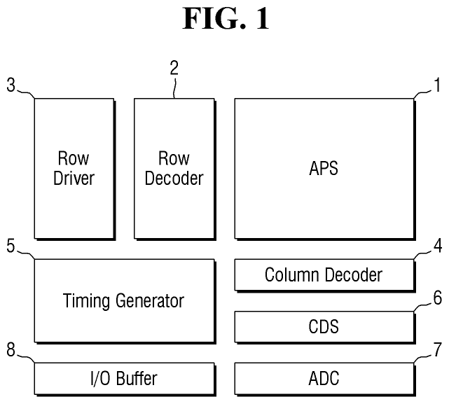

Also, in the present disclosure, the term “same” is not only completely identical but also includes a minute difference that may occur due to a process margin or the like. Hereinafter, an image sensor according to example embodiments will be described with reference to FIGS. 1 to 13.

FIG. 1 is an example block diagram illustrating an image sensor according to some embodiments.

Referring to FIG. 1, the image sensor according to some embodiments includes an active pixel sensor array (APS) 1, a row decoder 2, a row driver 3, a column decoder 4, a timing generator 5, a correlated double sampler (CDS) 6, an analog-to-digital converter (ADS) 7, and an input/output (I/O) buffer 8.

The active pixel sensor array 1 includes a plurality of unit pixels that are two-dimensionally arranged, and may convert an optical signal into an electrical signal. The active pixel sensor array 1 may be driven by a plurality of drive signals such as a pixel selection signal, a reset signal, and a charge transmission signal from the row driver 3. In addition, the electrical signal converted by the active pixel sensor array 1 may be provided to the correlated double sampler 6.

The row driver 3 may provide a plurality of driving signals for driving the plurality of unit pixels to the active pixel sensor array 1 in accordance with a result decoded by the row decoder 2. When the unit pixels are arranged in the form of a matrix, driving signals may be provided for each row.

The timing generator 5 may provide a timing signal and a control signal to the row decoder 2 and the column decoder 4.

The correlated double sampler (CDS) 6 may receive, hold and sample an electrical signal generated by the active pixel sensor array 1. The correlated double sampler 6 may doubly sample a specific noise level and a signal level by the electrical signal to output a difference level corresponding to a difference between the noise level and the signal level.

The analog-to-digital converter (ADC) 7 may convert an analog signal corresponding to the difference level output from the correlated double sampler 6 into a digital signal and output the converted signal.

The input/output buffer 8 may latch a digital signal, and sequentially output the latched digital signal to an image signal processor (not shown) in accordance with a decoding result of the column decoder 4.

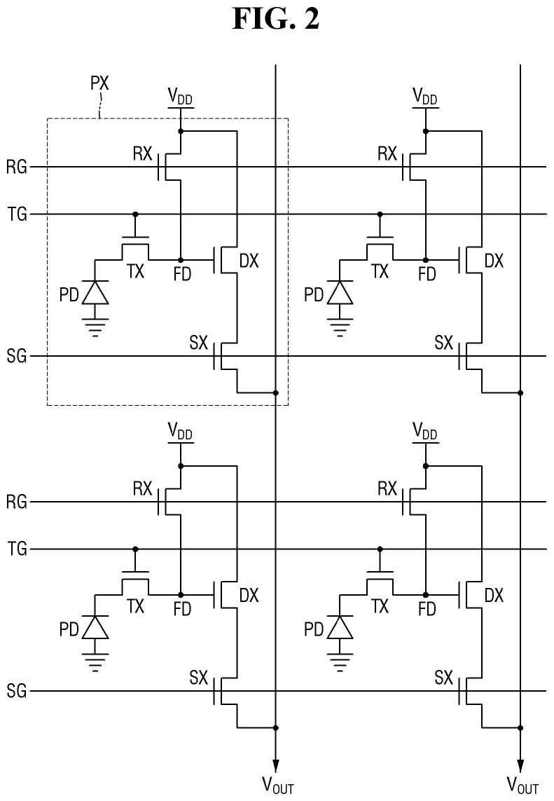

FIG. 2 is an example circuit diagram illustrating an image sensor according to some embodiments.

Referring to FIG. 2, the image sensor according to some embodiments includes a plurality of unit pixels PX.

The plurality of unit pixels PX may be arranged two-dimensionally (e.g., in the form of matrix). Each of the unit pixels PX may include a photoelectric conversion device PD, a transmission transistor TX, a floating diffusion region FD, a reset transistor RX, a drive transistor DX, and a selection transistor SX.

The photoelectric conversion device PD may generate charges in proportion to the amount of light incident from the outside. The photoelectric conversion device PD may be coupled with the transmission transistor TX that transmits the generated and accumulated charges to the floating diffusion region FD. The floating diffusion region FD is a region for converting charges into a voltage, and since the floating diffusion region FD has parasitic capacitance, charges may be cumulatively stored therein.

One end of the transmission transistor TX may be connected to the photoelectric conversion device PD, and the other end of the transmission transistor TX may be connected to the floating diffusion region FD. The transmission transistor TX may be formed as a transistor driven by a predetermined bias (e.g., the transmission signal TG). That is, the transmission transistor TX may transmit the charges generated from the photoelectric conversion device PD to the floating diffusion region FD in accordance with the transmission signal TG.

The drive transistor DX may be provided as a source follower buffer amplifier. The drive transistor DX may amplify a change in an electrical potential of the floating diffusion region FD that has received the charges from the photoelectric conversion device PD and output the amplified change in the electrical potential to an output line VOUT. When the drive transistor DX is turned on, a predetermined electrical potential provided to a drain of the drive transistor DX, for example, a power voltage VDD, may be transferred to a drain region of the selection transistor SX.

The selection transistor SX may select a unit pixel PX to be read in a row unit. The selection transistor SX may be a transistor that is driven by a selection line that applies a predetermined bias (e.g., a row selection signal SG).

The reset transistor RX may periodically reset the floating diffusion region FD. The reset transistor RX may be a transistor that is driven by a reset line that applies a predetermined bias (e.g., a reset signal RG). When the reset transistor RX is turned on by the reset signal RG, a predetermined electrical potential provided to a drain of the reset transistor RX, for example, a power supply voltage VDD may be transferred to the floating diffusion region FD to reset the floating diffusion region FD.

In FIG. 2, each of the unit pixels PX includes one photoelectric conversion device PD and four transistors TX, RX, DX and SX, but this is only an example. As another example, at least one of the reset transistor RX, the drive transistor DX or the selection transistor SX may be shared by unit pixels PX adjacent to each other.

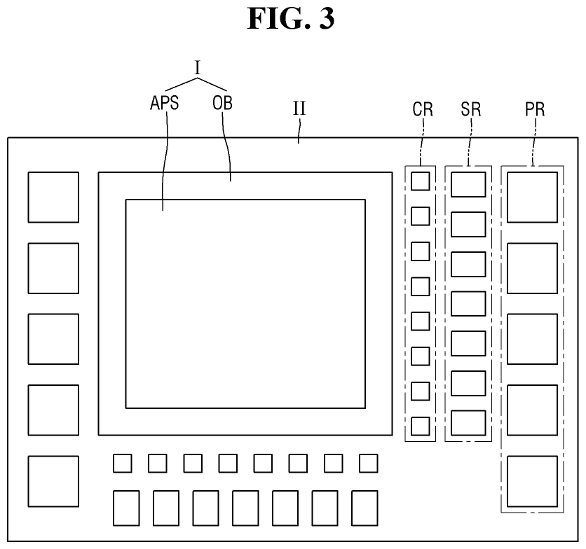

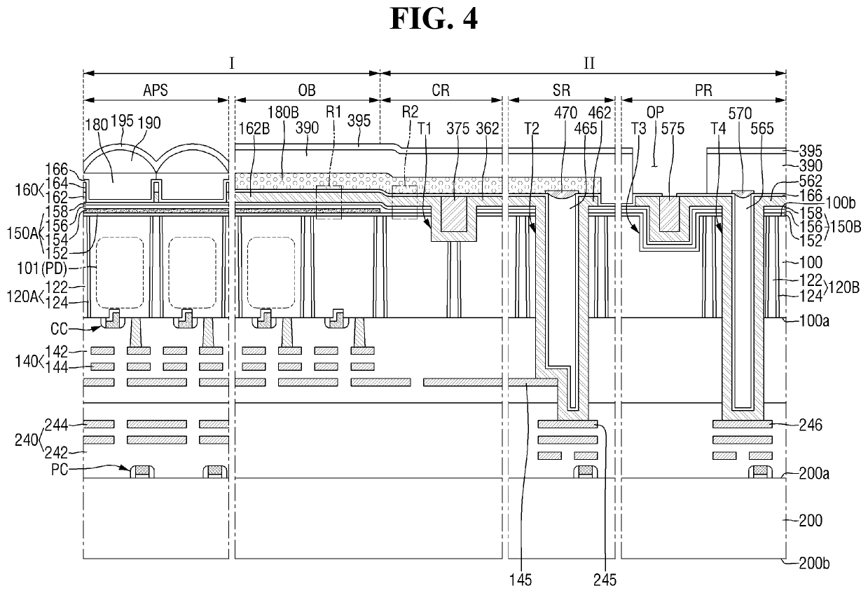

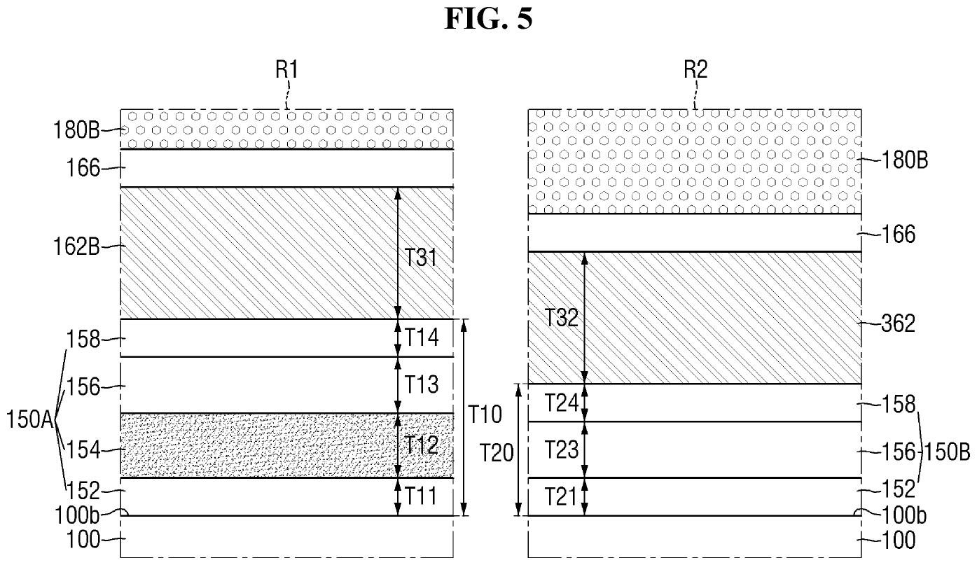

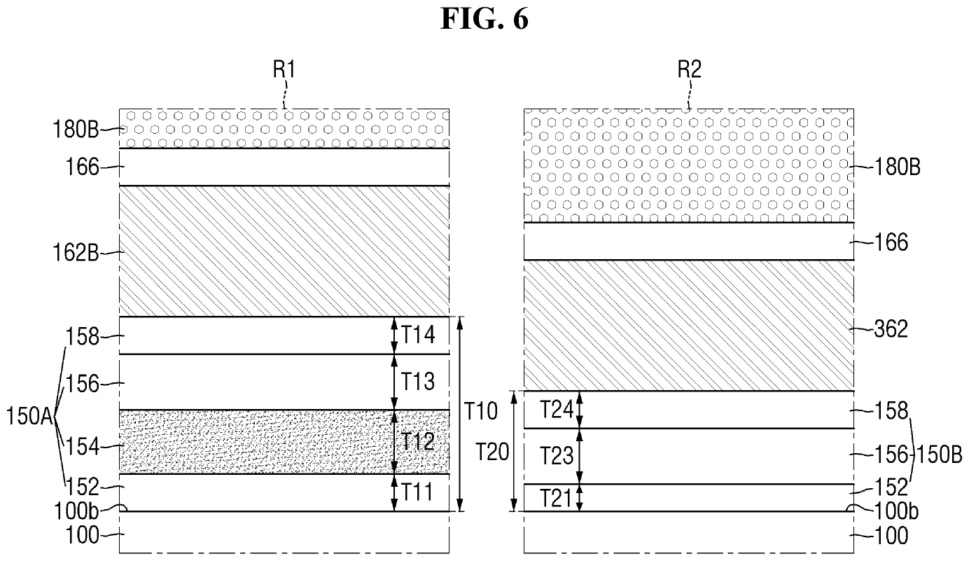

FIG. 3 is an example layout view illustrating an image sensor according to some embodiments. FIG. 4 is a schematic cross-sectional view illustrating an image sensor according to some embodiments. FIGS. 5 and 6 are various enlarged views illustrating a region R1 and a region R2 of FIG. 4, respectively.

Referring to FIG. 3, the image sensor according to some embodiments includes a first region I and a second region II.

The first region I may include a region corresponding to the active pixel sensor array 1 of FIG. 1. For example, a plurality of unit pixels (e.g., PX of FIG. 2) arranged two-dimensionally (e.g., in the form of matrix) may be formed in the first region I.

The first region I may include a light-receiving region APS and a light-blocking region OB. Active pixels for receiving light to generate an active signal may be arranged in the light-receiving region APS. Optical black pixels for generating an optical black signal by blocking light may be arranged in the light-blocking region OB. The light-blocking region OB may surround the periphery of the light-receiving region APS in a plan view, but this is only an example.

The second region II may be formed in the periphery of the first region I. For example, the second region II may surround the periphery of the first region I. In some embodiments, the second region II may include a contact region CR, a stack region SR, and a pad region PR. Lines may be disposed in the contact region CR and the stack region SR to transmit and receive the electrical signal of the first region I. The pad region PR may be connected to an external device to transmit and receive an electrical signal between the image sensor and the external device. In FIG. 3, the number and arrangement of the contact region CR, the stack region SR, and the pad region PR are only examples, and are not limited thereto.

Referring to FIGS. 3 to 6, the image sensor according to some embodiments may include a first substrate 100, a photoelectric conversion region 101, a first element isolation pattern 120A, a first circuit element CC, a first wiring structure 140, a first anti-reflection layer 150A, a second anti-reflection layer 150B, a grid pattern 160, a first passivation layer 166, a color filter 180, a microlens 190, a second passivation layer 195, a light-blocking pattern 162B, a light-blocking filter 180B, a planarization layer 390, a third passivation layer 395, a second substrate 200, a second circuit element PC, a second wiring structure 240, a first conductive pattern 362, a second conductive pattern 462, a third conductive pattern 562, and a second element isolation pattern 120B.

The first substrate 100 may be a semiconductor substrate. For example, the first substrate 100 may be bulk silicon or a silicon-on-insulator (SOI). The first substrate 100 may be a silicon substrate, or may include other materials such as silicon germanium, indium antimonide, lead telluride, indium arsenide, indium phosphide, gallium arsenide, or gallium antimonide. Alternatively, the first substrate 100 may have an epitaxial layer formed on a base substrate. For convenience of description, in the following embodiments, the first substrate 100 is a silicon substrate.

The first substrate 100 may include a first surface 100a and a second surface 100b, which are opposite to each other. In the following embodiments, the first surface 100a may be referred to as a front side of the first substrate 100, and the second surface 100b may be referred to as a back side of the first substrate 100. In some embodiments, the second surface 100b of the first substrate 100 may be a light-receiving surface on which light is incident. That is, the image sensor according to some embodiments may be a backside illumination (BSI) type image sensor.

The plurality of unit pixels (e.g., PX of FIG. 2) may be arranged in the first substrate 100 of the first region I. For example, active pixels for receiving light to generate an active signal may be arranged in the first substrate 100 of the light-receiving region APS. Optical black pixels for generating an optical black signal by blocking light may be arranged in the first substrate 100 of the light-blocking region OB. Although not shown in detail, dummy pixels may be formed in a portion of the light-receiving region APS adjacent to the light-blocking region OB.

In some embodiments, the first substrate 100 may have a first conductivity type. The first conductivity type may be, for example, a p-type. For example, the first substrate 100 may include p-type impurities (e.g., boron (B), aluminum (Al), indium (In), or gallium (Ga)), but this is only an example, and the first conductivity type may be an n-type.

The photoelectric conversion region 101 may be formed in the first substrate 100 of the first region I. The photoelectric conversion region 101 may be formed in each unit pixel (e.g., PX of FIG. 2) arranged in the first substrate 100 of the first region I. For example, the plurality of photoelectric conversion regions 101 may be arranged two-dimensionally (e.g., in the form of matrix) within the first substrate 100 of the first region I. The photoelectric conversion region 101 may correspond to the photoelectric conversion device PD of FIG. 2. That is, the photoelectric conversion region 101 may generate charges in proportion to the amount of light incident from the outside.

The photoelectric conversion region 101 may have a second conductivity type different from the first conductivity type. For example, the photoelectric conversion region 101 may be formed by ion implantation of n-type impurities into the p-type first substrate 100.

In some embodiments, the photoelectric conversion region 101 may be formed in a portion of the light-blocking region OB, and may not be formed in another portion of the light-blocking region OB. For example, the photoelectric conversion region 101 may be formed in a portion of the light-blocking region OB adjacent to the light-receiving region APS, but may not be formed in another portion of the light-blocking region OB spaced apart from the light-receiving region APS.

The first element isolation pattern 120A may be formed in the first substrate 100. For example, the first element isolation pattern 120A may be extended from the first surface 100a of the first substrate 100 toward the second surface 100b of the first substrate 100. The first element isolation pattern 120A may include or may be formed of an insulating material, for example, at least one of silicon oxide, silicon nitride, silicon oxynitride or their combination, but is not limited thereto.

The first element isolation pattern 120A may define a plurality of unit pixels (e.g., PX in FIG. 2) in the first substrate 100. For example, the first element isolation pattern 120A may be formed in a lattice shape in the first substrate 100 to surround each of the photoelectric conversion regions 101 arranged in the form of matrix. The first element isolation pattern 120A may improve light condensing efficiency by refracting or reflecting light obliquely incident to the photoelectric conversion region 101. In addition, the first element isolation pattern 120A may prevent photocharges generated from a specific unit pixel from moving to another adjacent unit pixel by a random drift.

In some embodiments, a width of the first element isolation pattern 120A may be reduced as it is directed from the first surface 100a toward the second surface 100b. For example, the first element isolation pattern 120A may be formed by burying an insulating material in a deep trench formed by patterning the first substrate 100 including the first surface 100a. In some other embodiments, unlike the shown example, the width of the first element isolation pattern 120A may be increased as it is directed from the first surface 100a toward the second surface 100b. For example, the first element isolation pattern 120A may be formed by burying an insulating material in a deep trench formed by patterning the first substrate 100 including the second surface 100b.

In some embodiments, the first element isolation pattern 120A may completely pass through the first substrate 100. For example, the first element isolation pattern 120A may be exposed by the second surface 100b of the first substrate 100.

In some embodiments, the first element isolation pattern 120A may include a filling pattern 122 and a spacer layer 124.

The filling pattern 122 may be extended from the first surface 100a of the first substrate 100 toward the second surface 100b of the first substrate 100. The filling pattern 122 may include or may be formed of a conductive material, for example, polysilicon, but is not limited thereto. In some embodiments, a ground voltage or a minus voltage may be applied to the filling pattern 122. The filling pattern 122 may prevent charges generated by electrostatic discharge (ESD) from being accumulated on the surface (e.g., the second surface 100b) of the first substrate 100, thereby effectively preventing ESD bruise defects from occurring.

The spacer layer 124 may be extended along a side of the filling pattern 122. The spacer layer 124 may include or may be formed of an insulating material, for example, at least one of silicon oxide, aluminum oxide, tantalum oxide, or their combination, but is not limited thereto. The spacer layer 124 may be interposed between the filling pattern 122 and the first substrate 100 to electrically separate the filling pattern 122 from the first substrate 100.

The first circuit element CC may be formed on the first surface 100a of the first substrate 100. The first circuit element CC may include various transistors for processing electrical signals generated from the respective unit pixels (e.g., PX in FIG. 2) in the first substrate 100. For example, the first circuit element CC may include the transmission transistor TX, the reset transistor RX, the drive transistor DX, or the selection transistor SX, which is described above with reference to FIG. 2.

In some embodiments, the first circuit element CC may include a vertical transmission transistor. For example, a portion of the first circuit element TRI including the transmission transistor TX described above may be extended into the first substrate 110. The vertical transmission transistor may reduce an area of a unit pixel, thereby contributing to high integration of the image sensor.

The first wiring structure 140 may be formed on the first surface 100a of the first substrate 100. The first wiring structure 140 may include a plurality of wiring patterns. For example, the first wiring structure 140 may include a first inter-wiring insulating layer 142 on the first surface 100a and a first wiring pattern 144 in the first inter-wiring insulating layer 142. In FIG. 4, the number of layers and arrangement of the first wiring patterns 144 are only examples, and the present disclosure is not limited thereto. The first wiring structure 140 may be electrically connected to the first circuit element CC to transmit and receive an electrical signal to and from each unit pixel of the first region I.

The first anti-reflection layer 150A may be formed on the second surface 100b of the first substrate 100 of the first region I. The first anti-reflection layer 150A may be extended to be conformal along the second surface 100b of the first substrate 100 of the first region I. The first anti-reflection layer 150A may prevent reflection of light incident on the second surface 100b of the first substrate 100. For example, the first anti-reflection layer 150A may be formed as a multi-layer in which material layers having different refractive indices are alternately stacked. In addition, the first anti-reflection layer 150A may contribute to the formation of a color filter 180 and a micro lens 190, which will be described later, at a uniform height.

In some embodiments, the first anti-reflection layer 150A may be formed as a multi-layer that includes at least one insulating material layer and at least one conductive material layer. For example, the first anti-reflection layer 150A may include a first insulating material layer 152, a conductive material layer 154, a second insulating material layer 156 and a third insulating material layer 158, which are sequentially stacked on the second surface 100b of the first substrate 100, but this is only an example. The number of layers of the first anti-reflection layer 150A is not limited to the shown example.

Each of the first insulating material layer 152, the second insulating material layer 156 and the third insulating material layer 158 may include or may be formed of an insulating material, for example, at least one of silicon oxide, silicon nitride, silicon oxynitride, aluminum oxide, hafnium oxide, or their combination, but is not limited thereto. In some embodiments, each of the first insulating material layer 152, the second insulating material layer 156 and the third insulating material layer 158 may include or may be formed of insulating oxide. For example, the first insulating material layer 152 may include or may be formed of aluminum oxide (AlO), the second insulating material layer 156 may include or may be formed of plasma enhanced oxide (PEOX), and the third insulating material layer 158 may include or may be formed of hafnium oxide (HfO).

The conductive material layer 154 may have a refractive index different from that of the insulating oxide. For example, the conductive material layer 154 may include or may be formed of a conductive oxide different from that of the insulating oxide. For example, the conductive material layer 154 may include or may be formed of titanium oxide (TiO).

The second anti-reflection layer 150B may be formed on the second surface 100b of the first substrate 100 of the second region II. The second anti-reflection layer 150B may be extended to be conformal along the second surface 100b of the first substrate 100 of the second region II from the first anti-reflection layer 150A. The second anti-reflection layer 150B may include a portion of a material layer included in the first anti-reflection layer 150A. For example, the second anti-reflection layer 150B may include at least one insulating material layer included in the first anti-reflection layer 150A.

In some embodiments, the second anti-reflection layer 150B may not include the conductive material layer 154 included in the first anti-reflection layer 150A. For example, the second anti-reflection layer 150B may include a first insulating material layer 152, a second insulating material layer 156 and a third insulating material layer 158, which are sequentially stacked on the second surface 100b of the first substrate 100, but this is only an example. The number of layers of the second anti-reflection layer 150B is not limited to the shown example.

In detail, the first insulating material layer 152 may be extended along the second surface 100b of the first substrate 100 over the first region I and the second region II. The conductive material layer 154 of the first anti-reflection layer 150A may be extended along the first insulating material layer 152 of the first region I, and may not be extended along the first insulating material layer 152 of the second region II. The second insulating material layer 156 may be extended along the conductive material layer 154 on the first region I, and then may be extended along the first insulating material layer 152 on the second region II. The third insulating material layer 158 may be extended along the second insulating material layer 156 over the first region I and the second region II. In some embodiments, the second insulating material layer 156 on the second region II may be formed directly on the first insulating material layer 152 and thus may be in contact with the first insulating material layer 152. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

As the second anti-reflection layer 150B does not include a conductive material layer 154 included in the first anti-reflection layer 150A, a thickness T20 of the second anti-reflection layer 150B may be smaller than a thickness T10 of the first anti-reflection layer 150A. For example, as shown in FIG. 5, thicknesses T11, T13 and T14 of the first to third insulating material layers 158 of the first anti-reflection layer 150A may be the same as thicknesses T21, T23, and T24 of the first to third insulating material layers 158 of the second anti-reflection layer 150B. In this case, the thickness T20 of the second anti-reflection layer 150B may be smaller than the thickness T10 of the first anti-reflection layer 150A by as much as the thickness T12 of the conductive material layer 154.

In some embodiments, the thickness T21 of the first insulating material layer 152 of the second anti-reflection layer 150B may be equal to or smaller than the thickness T11 of the first insulating material layer 152 of the first anti-reflection layer 150A. For example, as shown in FIG. 6, the thickness T21 of the first insulating material layer 152 of the second anti-reflection layer 150B may be smaller than the thickness T11 of the first insulating material layer 152 of the first anti-reflection layer 150A. In this case, the thickness T20 of the second anti-reflection layer 150B may be smaller than the thickness T10 of the first anti-reflection layer 150A by as much as the thickness T12 or more of the conductive material layer 154.

The grid pattern 160 may be formed on the first anti-reflection layer 150A of the light-receiving region APS. The grid pattern 160 may define the plurality of unit pixels (e.g., PX of FIG. 2) on the first substrate 100. For example, the grid pattern 160 may be disposed to overlap at least a portion of the first element isolation pattern 120A in a vertical direction.

In some embodiments, the grid pattern 160 may include a metal pattern 162 and a low refractive index pattern 164. The metal pattern 162 and the low refractive index pattern 164 may be sequentially stacked on the first anti-reflection layer 150A.

The metal pattern 162 may include or may be formed of at least one of, for example, titanium (Ti), titanium nitride (TiN), tantalum (Ta), tantalum nitride (TaN), tungsten (W), aluminum (Al), copper (Cu) or their combination, but is not limited thereto. The metal pattern 162 may prevent charges generated by electrostatic discharge (ESD) from being accumulated on the surface (e.g., the second surface 100b) of the first substrate 100, thereby effectively preventing ESD bruise defects from occurring.

The low refractive index pattern 164 may include a low refractive index material having a refractive index lower than that of silicon (Si). For example, the low refractive index pattern 164 may include or may be formed of at least one of silicon oxide, aluminum oxide, tantalum oxide or their combination, but is not limited thereto. The low refractive index pattern 164 may improve light condensing efficiency by refracting or reflecting light obliquely incident on the second surface 100b of the light-receiving region APS.

The first passivation layer 166 may be formed on the first anti-reflection layer 150A and the grid pattern 160. The first passivation layer 166 may be extended to be conformal along a profile of the first anti-reflection layer 150A and the grid pattern 160. The first passivation layer 166 may prevent the first anti-reflection layer 150A and the grid pattern 160 from being damaged. The first passivation layer 166 may include or may be formed of, for example, aluminum oxide (AlO), but is not limited thereto.

The color filter 180 may be formed on the first passivation layer 166 of the light-receiving region APS. The color filter 180 may be arranged to correspond to the respective unit pixels (e.g., PX in FIG. 2). For example, the plurality of color filters 180 may be arranged two-dimensionally (e.g., in the form of matrix) to correspond to the plurality of photoelectric conversion regions 101. The grid pattern 160 may be formed in a lattice shape to surround each of the color filters 180 arranged in the form of matrix.

The color filter 180 may have various colors in accordance with unit pixels. For example, the color filter 180 may include a red color filter, a green color filter, a blue color filter, a yellow filter, a magenta filter, and a cyan filter, and may further include a white filter.

The microlens 190 may be formed on the color filter 180. The microlens 190 may be arranged to correspond to each of the unit pixels (e.g., PX of FIG. 2). For example, the plurality of microlenses 190 may be arranged two-dimensionally (e.g., in the form of matrix) to correspond to the plurality of photoelectric conversion regions 101.

The microlens 190 has a convex shape, and may have a predetermined radius of curvature. Therefore, the microlens 190 may condense light incident on the photoelectric conversion region 101. The microlens 190 may include, for example, a light-transmissive resin, but is not limited thereto.

The second passivation layer 195 may be formed on the microlens 190. The second passivation layer 195 may be extended along a surface of the microlens 190. The second passivation layer 195 may include or may be formed of, for example, an inorganic oxide film such as a silicon oxide film, a titanium oxide film, a zirconium oxide film, or a hafnium oxide film, but is not limited thereto. For example, the second passivation layer 195 may include a low temperature oxide (LTO).

The second passivation layer 195 may protect the microlens 190 from the outside. For example, the second passivation layer 195 may include the inorganic oxide film to protect the microlens 190 including an organic material. In addition, the second passivation layer 195 may improve quality of the image sensor by improving light condensing efficiency of the microlens 190. For example, the second passivation layer 195 may reduce reflection, refraction, and scattering of incident light reaching a space between the microlenses 190 by filling the space between the microlenses 190.

The light-blocking pattern 162B may be formed on the first anti-reflection layer 150A of the light-blocking region OB. For example, the light-blocking pattern 162B may be extended to be conformal along an upper surface of the first anti-reflection layer 150A. The light-blocking pattern 162B may cover at least a portion of the first anti-reflection layer 150A of the light-blocking region OB. In some embodiments, the first passivation layer 166 may be further extended along an upper surface of the light-blocking pattern 162B.

The light-blocking pattern 162B may block light incident on the second surface 100b of the light-blocking region OB. The light-blocking pattern 162B may include or may be formed of at least one of, for example, titanium (Ti), titanium nitride (TiN), tantalum (Ta), tantalum nitride (TaN), tungsten (W), aluminum (Al), copper (Cu), or their combination, but is not limited thereto.

The light-blocking filter 180B may be formed on the light-blocking pattern 162B. For example, the light-blocking filter 180B may be extended to be conformal along an upper surface of the first passivation layer 166 of the light-blocking region OB. The light-blocking filter 180B may cover at least a portion of the light-blocking pattern 162B.

The light-blocking filter 180B may block light incident on the second surface 100b of the light-blocking region OB together with the light-blocking pattern 162B. For example, the light-blocking filter 180B may include a blue color filter to block infrared light that is not blocked by the light-blocking pattern 162B.

The planarization layer 390 may be formed on the light-blocking filter 180B. The planarization layer 390 may cover the light-blocking region OB and the second region II. In some embodiments, the planarization layer 390 may be formed at the same level as the microlens 190. In the present disclosure, “formed at the same level” refers to “formed by the same fabricating process.” For example, the planarization layer 390 may include a light-transmissive resin included in the microlens 190.

The third passivation layer 395 may be formed on the planarization layer 390. The third passivation layer 395 may be extended along an upper surface of the planarization layer 390. In some embodiments, the third passivation layer 395 may be formed at the same level as the second passivation layer 195. For example, the third passivation layer 395 may include a low temperature oxide (LTO) included in the second passivation layer 195. The third passivation layer 395 may protect the planarization layer 390 from the outside.

The second substrate 200 may be a bulk silicon or a silicon-on-insulator (SOI). The second substrate 200 may be a silicon substrate, or may include or may be formed of other materials such as silicon germanium, indium antimonide, lead telluride, indium arsenide, indium phosphide, gallium arsenide, or gallium antimonide. Alternatively, the second substrate 200 may have an epitaxial layer formed on the base substrate. For convenience of description, in the following embodiments, the second substrate 200 is a silicon substrate.

The second substrate 200 may include a third surface 200a and a fourth surface 200b, which are opposite to each other. In the following embodiments, the third surface 200a may be referred to as a front side of the second substrate 200, and the fourth surface 200b may be referred to as a back side of the second substrate 200. In some embodiments, the third surface 200a of the second substrate 200 may face the first surface 100a of the first substrate 100.

The second circuit element PC may be formed on the third surface 200a of the second substrate 200. The second circuit element PC may be electrically connected to the first region I to transmit and receive an electrical signal to and from each unit pixel of the first region I. For example, the second circuit element PC may include circuit elements constituting the row decoder 2, the row driver 3, the column decoder 4, the timing generator 5, the correlated double sampler 6, the analog-to-digital converter 7, the input/output buffer 8, etc., which are described above with reference to FIG. 1.

The second wiring structure 240 may be formed on the third surface 200a of the second substrate 200. The second wiring structure 240 may include a plurality of wiring patterns. For example, the second wiring structure 240 may include a second wiring pattern 244. In FIG. 4, the number of layers and arrangement of the second wiring patterns 244 are only examples, and the present disclosure is not limited thereto. The second wiring structure 240 may be electrically connected to the second circuit element PC.

The first wiring structure 140 and the second wiring structure 240 may be bonded to each other. For example, as shown in FIG. 4, a lower surface of the first wiring structure 140 may be attached onto an upper surface of the second wiring structure 240. The first wiring structure 140 and the second wiring structure 240 may be bonded to each other by, for example, a wafer bonding process, but are not limited thereto.

The first conductive pattern 362 may be formed on the second anti-reflection layer 150B of the contact region CR. At least a portion of the first conductive pattern 362 may pass through the second anti-reflection layer 150B. For example, a first trench T1 may be formed in the first substrate 100 and the second anti-reflection layer 150B of the contact region CR. At least a portion of the first conductive pattern 362 may be extended to be conformal along a profile of the first trench T1.

In some embodiments, a portion of the first conductive pattern 362 may be further extended along an upper surface of the second anti-reflection layer 150B. In FIG. 4, the first conductive pattern 362 is only shown as being connected to the light-blocking pattern 162B, but this is only an example, and the first conductive pattern 362 may be spaced apart from the light-blocking pattern 162B. In some embodiments, the first passivation layer 166 may be further extended along an upper surface of the first conductive pattern 362.

The first conductive pattern 362 may include or may be formed of at least one of, for example, titanium (Ti), titanium nitride (TiN), tantalum (Ta), tantalum nitride (TaN), tungsten (W), aluminum (Al), copper (Cu) or their combination, but is not limited thereto.

In some embodiments, a contact pattern 375 for filling the first trench T1 may be formed on the first conductive pattern 362. The contact pattern 375 may include or may be formed of a conductive material, at least one of for example, tungsten (W), copper (Cu), aluminum (Al), gold (Au), silver (Ag) or their alloy, but is not limited thereto. In some embodiments, the first passivation layer 166 may be further extended along an upper surface of the contact pattern 375.

The first conductive pattern 362 and/or the contact pattern 375 may be electrically connected to the filling pattern 122 of the first element isolation pattern 120A. For example, the first trench T1 may expose a portion of the filling pattern 122 in the contact region CR. The first conductive pattern 362 may be extended along the first trench T1 to contact the filling pattern 122. The filling pattern 122 may receive a ground voltage or a minus voltage through the first conductive pattern 362.

The second conductive pattern 462 may be formed on the second anti-reflection layer 150B of the stack region SR. At least a portion of the second conductive pattern 462 may pass through the second anti-reflection layer 150B. For example, a second trench T2 may be formed in the first substrate 100 and the second anti-reflection layer 150B of the stack region SR. At least a portion of the second conductive pattern 462 may be extended to be conformal along a profile of the second trench T2.

In some embodiments, a portion of the second conductive pattern 462 may be further extended along the upper surface of the second anti-reflection layer 150B. The second conductive pattern 462 may be connected to the first conductive pattern 362, or may be spaced apart from the first conductive pattern 362. In some embodiments, the first passivation layer 166 may be further extended along an upper surface of the second conductive pattern 462.

The second conductive pattern 462 may include or may be formed of at least one of, for example, titanium (Ti), titanium nitride (TiN), tantalum (Ta), tantalum nitride (TaN), tungsten (W), aluminum (Al), copper (Cu) or their combination, but is not limited thereto.

In some embodiments, a first filling insulating layer 465 for filling the second trench T2 may be formed on the second conductive pattern 462. The first filling insulating layer 465 may include or may be formed of an insulating material, for example, at least one of silicon oxide, aluminum oxide, tantalum oxide or their combination, but is not limited thereto. In some embodiments, the first passivation layer 166 may be interposed between the second conductive pattern 462 and the first filling insulating layer 465.

In some embodiments, a first capping pattern 470 may be formed on the first filling insulating layer 465. The first capping pattern 470 may cover an upper surface of the first filling insulating layer 465.

The second conductive pattern 462 may electrically connect the first wiring structure 140 with the second wiring structure 240. For example, the second trench T2 may expose a first wiring 145 of the first wiring structure 140 of the stack region SR and a second wiring 245 of the second wiring structure 240 of the stack region SR by passing through the first substrate 100 and the first inter-wiring insulating layer 142. The second conductive pattern 462 may be extended along the second trench T2 to connect the first wiring 145 with the second wiring 245.

The third conductive pattern 562 may be formed on the second anti-reflection layer 150B of the pad region PR. At least a portion of the third conductive pattern 562 may pass through the second anti-reflection layer 150B. For example, a third trench T3 may be formed in the first substrate 100 of the pad region PR, and a fourth trench T4 may be formed in the first substrate 100 and the second anti-reflection layer 150B of the pad region PR. At least a portion of the third conductive pattern 562 may be extended to be conformal along a profile of the third trench T3 and the fourth trench T4.

In some embodiments, a portion of the third conductive pattern 562 may be further extended along the upper surface of the second anti-reflection layer 150B. In some embodiments, the first passivation layer 166 may be further extended along an upper surface of the third conductive pattern 562.

The third conductive pattern 562 may include or may be formed of at least one of, for example, titanium (Ti), titanium nitride (TiN), tantalum (Ta), tantalum nitride (TaN), tungsten (W), aluminum (Al), copper (Cu) or their combination, but is not limited thereto.

In some embodiments, a pad pattern 575 for filling the third trench T3 may be formed on the third conductive pattern 562. The pad pattern 575 may include or may be formed of a conductive material, for example, at least one of tungsten (W), copper (Cu), aluminum (Al), gold (Au), silver (Ag) or their alloy, but is not limited thereto. In some embodiments, an opening in the first passivation layer 166, the planarization layer 390 and the third passivation layer 395 may expose at least a portion of the upper surface of the pad pattern 575. For example, an opening OP for exposing at least a portion of the upper surface of the pad pattern 575 may be formed in the first passivation layer 166, the planarization layer 390 and the third passivation layer 395.

In some embodiments, a portion of the second anti-reflection layer 150B may be formed in the third trench T3. For example, a portion of the second anti-reflection layer 150B may be extended to be conformal along the profile of the third trench T3. The third conductive pattern 562 may fill at least a portion of the third trench T3 on the second anti-reflection layer 150B.

In some embodiments, a second filling insulating layer 565 for filling the fourth trench T4 may be formed on the third conductive pattern 562. The second filling insulating layer 565 may include or may be formed of an insulating material, for example, at least one of silicon oxide, aluminum oxide, tantalum oxide or their combination, but is not limited thereto. In some embodiments, the first passivation layer 166 may be interposed between the third conductive pattern 562 and the second filling insulating layer 565.

In some embodiments, a second capping pattern 570 may be formed on the second filling insulating layer 565. The second capping pattern 570 may cover an upper surface of the second filling insulating layer 565.

The third conductive pattern 562 may electrically connect the image sensor with the external device. For example, the fourth trench T4 may expose a third wiring 246 of the second wiring structure 240 of the pad region PR by passing through the first substrate 100 and the first inter-wiring insulating layer 142. The third conductive pattern 562 may be extended along the fourth trench T4 to contact the third wiring 246. In addition, the third conductive pattern 562 may be electrically connected to the external device through the pad pattern 575 exposed by the opening OP.

In some embodiments, the first conductive pattern 362, the second conductive pattern 462 and/or the third conductive pattern 562 may be formed at the same level as the light-blocking pattern 162B. For example, the first conductive pattern 362, the second conductive pattern 462, and/or the third conductive pattern 562 may include a metal material included in the light-blocking pattern 162B.

In some embodiments, a thickness of the first conductive pattern 362, the second conductive pattern 462 and/or the third conductive pattern 562 may be the same as that of the light-blocking pattern 162B. For example, as shown in FIG. 5, a thickness T31 of the light-blocking pattern 162B and a thickness T32 of the first conductive pattern 362 may be the same as each other.

The second element isolation pattern 120B may be formed in the first substrate 100 of the second region II. The second element isolation pattern 120B may be formed in the periphery of the first conductive pattern 362, the second conductive pattern 462 and/or the third conductive pattern 562. The second element isolation pattern 120B may include or may be formed of an insulating material, for example, at least one of silicon oxide, silicon nitride, silicon oxynitride or their combination, but is not limited thereto. The second element isolation pattern 120B may electrically isolate the first conductive pattern 362, the second conductive pattern 462, and/or the third conductive pattern 562 from each other in the first substrate 100.

In some embodiments, the second element isolation pattern 120B may be formed at the same level as the first element isolation pattern 120A. For example, the second element isolation pattern 120B may include the filling pattern 122 and the spacer layer 124.

An anti-reflection layer is used to prevent reflection of light incident on the light-receiving surface of the image sensor, and various material layers are being studied to improve efficiency of the anti-reflection layer. However, since a conductive material layer, such as titanium oxide, which is used as the anti-reflection layer, forms a leakage path in various conductive patterns (e.g., the first to third conductive patterns 362, 462 and 562) passing through the anti-reflection layer in order to transmit and receive an electrical signal of the image sensor, there is restriction in use.

In order to block the leakage path, cutting structures may be formed to cut the conductive material layer in a moat shape surrounding each of the conductive patterns (e.g., the first to third conductive patterns 362, 462 and 562). However, due to the diversity of the conductive patterns, a step different due to the cutting structures may be generated, which causes a defect of the image sensor.

Alternatively, the image sensor according to some embodiments may effectively block a leakage path, which is caused by the conductive material layer 154, by using the first anti-reflection layer 150A of the first region I and the second anti-reflection layer 150B of the second region II. In detail, as described above, the first anti-reflection layer 150A in the first region I in which the unit pixels (e.g., PX of FIG. 2) are disposed may include the conductive material layer 154, and the second anti-reflection layer 150B in the second region II in which the conductive patterns (e.g., the first to third conductive patterns 362, 462 and 562) are disposed may not include the conductive material layer 154. Therefore, regardless of the diversity of the conductive patterns (e.g., the first to third conductive patterns 362, 462 and 562), a leakage path due to the second anti-reflection layer 150B may be effectively blocked.

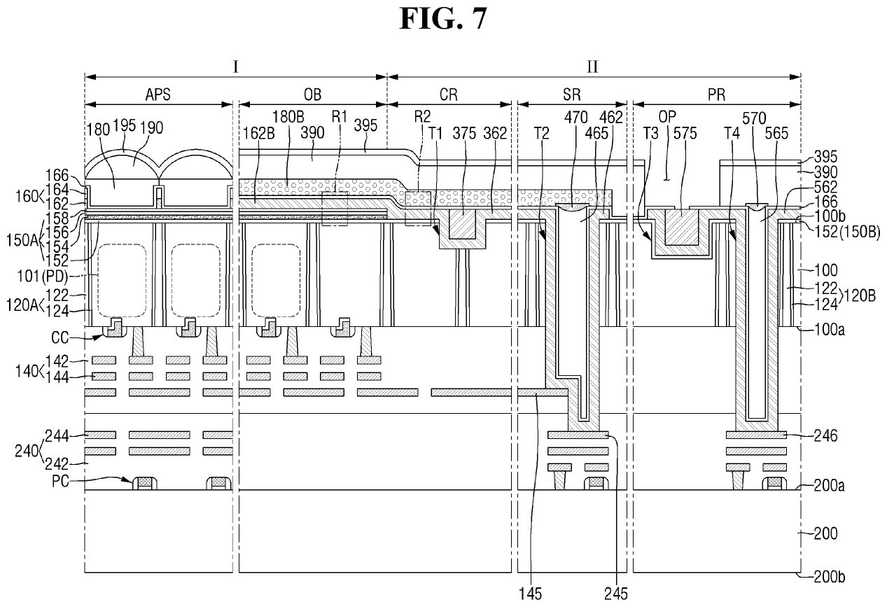

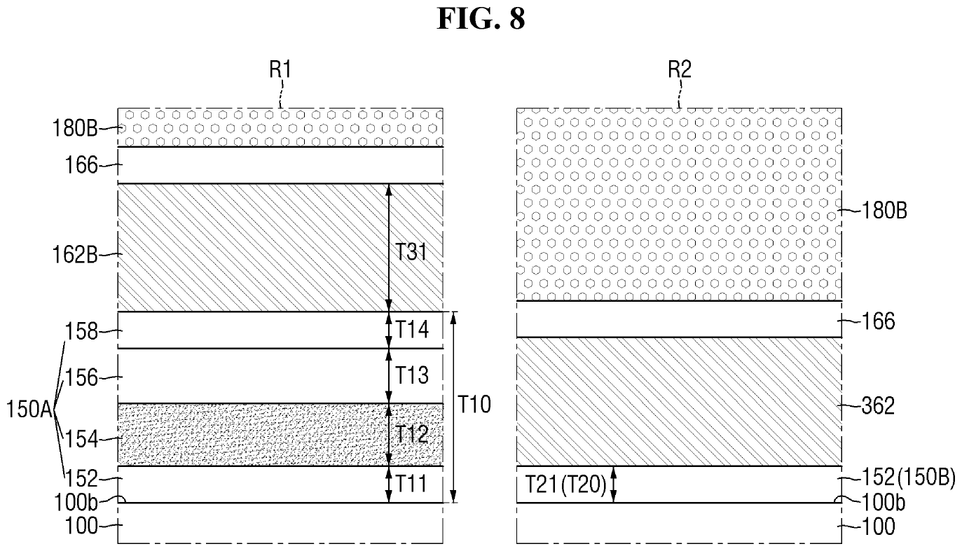

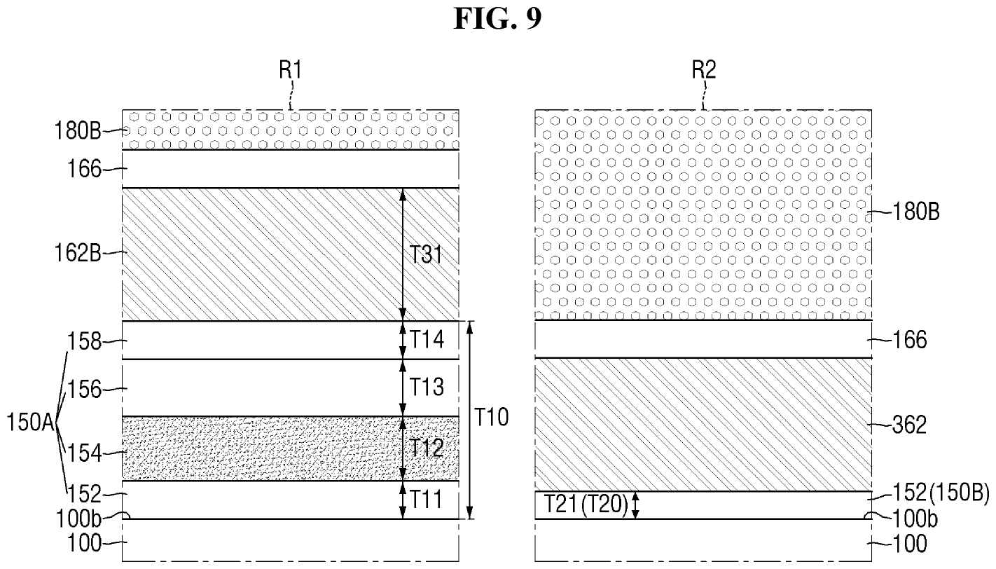

FIG. 7 is a schematic cross-sectional view illustrating an image sensor according to some embodiments. FIGS. 8 and 9 are various enlarged views illustrating a region R1 and a region R2 of FIG. 7, respectively. For convenience of description, portions duplicated with those described with reference to FIGS. 1 to 6 will be briefly described or omitted.

Referring to FIGS. 3 and 7 to 9, in the image sensor according to some embodiments, the second anti-reflection layer 150B may include the first insulating material layer 152.

The second anti-reflection layer 150B may not include material layers stacked on the conductive material layer 154 of the first anti-reflection layer 150A. In detail, the first insulating material layer 152 may be extended along the second surface 100b of the first substrate 100 over the first region I and the second region II. The conductive material layer 154, the second insulating material layer 156 and the third insulating material layer 158 of the first anti-reflection layer 150A may be extended along the first insulating material layer 152 of the first region I, and may not be extended along the first insulating material layer 152 of the second region II. In some embodiments, the first conductive pattern 362 may be formed on and in contact with the first insulating material layer 152.

The thickness T20 of the second anti-reflection layer 150B may be smaller than the thickness T10 of the first anti-reflection layer 150A as the second anti-reflection layer 150B does not include the conductive material layer 154, the second insulating material layer 156 and the third insulating material layer 158, which are included in the first anti-reflection layer 150A. For example, as shown in FIG. 8, the thickness T11 of the first insulating material layer 152 of the first anti-reflection layer 150A and the thickness T21 of the first insulating material layer 152 of the second anti-reflection layer 150B may be the same as each other. In this case, the thickness T20 of the second anti-reflection layer 150B may be smaller than the thickness T10 of the first anti-reflection layer 150A by as much as a sum (T12+T13+T14) of the thicknesses of the conductive material layer 154, the second insulating material layer 156 and the third insulating material layer 158.

In some embodiments, the thickness T21 of the first insulating material layer 152 of the second anti-reflection layer 150B may be equal to or smaller than the thickness T11 of the first insulating material layer 152 of the first anti-reflection layer 150A. For example, as shown in FIG. 9, the thickness T21 of the first insulating material layer 152 of the second anti-reflection layer 150B may be smaller than the thickness T11 of the first insulating material layer 152 of the first anti-reflection layer 150A. In this case, the thickness T20 of the second anti-reflection layer 150B may be smaller than the thickness T10 of the first anti-reflection layer 150A by as much as the sum (T12+T13+T14) or more of the thicknesses of the conductive material layer 154, the second insulating material layer 156 and the third insulating material layer 158.

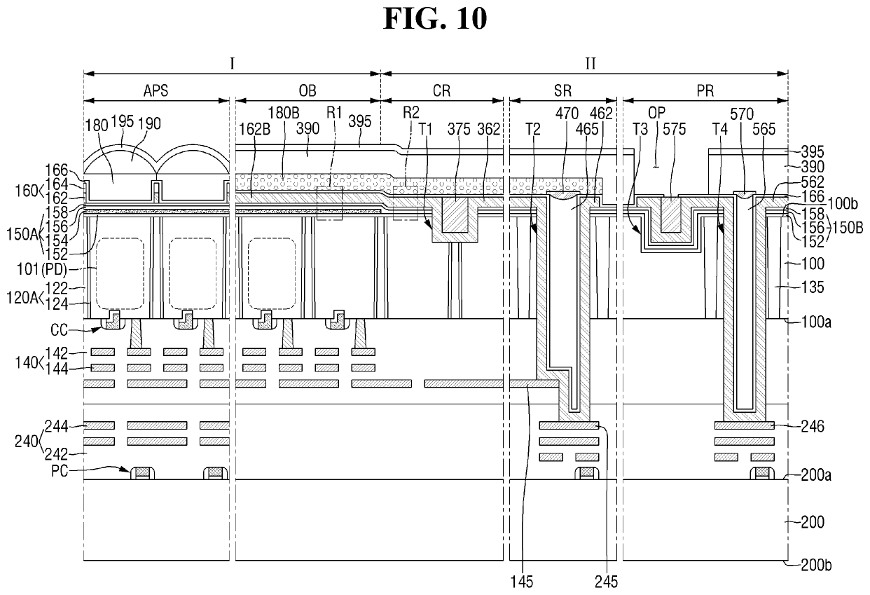

FIGS. 10 to 13 are various schematic cross-sectional views illustrating an image sensor according to some embodiments. For convenience of description, portions duplicated with those described with reference to FIGS. 1 to 9 will be briefly described or omitted.

Referring to FIG. 10, the image sensor according to some embodiments includes a third element isolation pattern 135.

The third element isolation pattern 135 may be formed in the first substrate 100 of the second region II. The third element isolation pattern 135 may be formed in the periphery of the first conductive pattern 362, the second conductive pattern 462 and/or the third conductive pattern 562. The third element isolation pattern 135 may include or may be formed of an insulating material, for example, at least one of silicon oxide, silicon nitride, silicon oxynitride or their combination, but is not limited thereto. The third element isolation pattern 135 may electrically isolate the first conductive pattern 362, the second conductive pattern 462 and/or the third conductive pattern 562 from each other in the first substrate 100.

In some embodiments, a width of the third element isolation pattern 135 may be reduced as it is directed toward the first surface 100a from the second surface 100b. For example, the third element isolation pattern 135 may be formed by burying an insulating material in a deep trench formed by patterning the first substrate 100 including the second surface 100a.

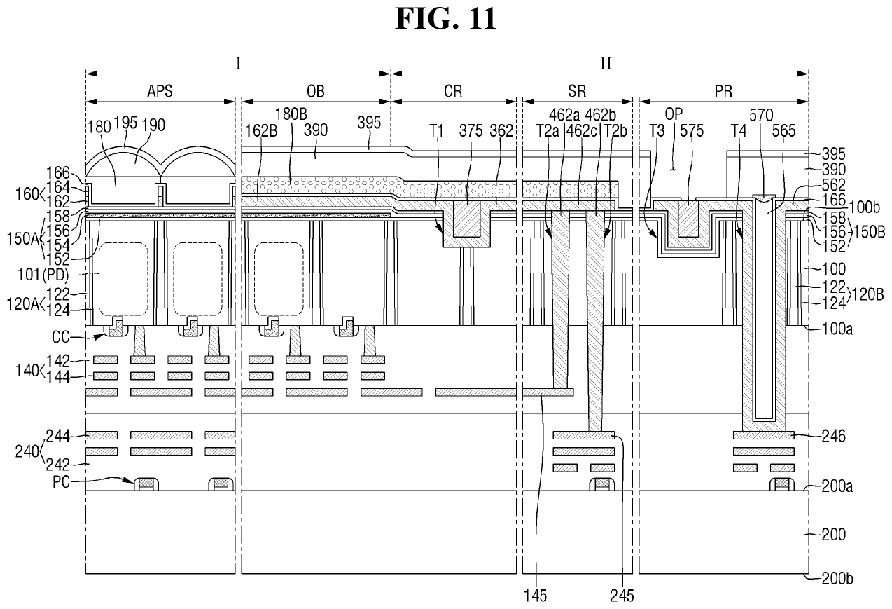

Referring to FIG. 11, the image sensor according to some embodiments includes a first through via 462a, a second through via 462b, and a fourth conductive pattern 462c.

The first through via 462a, the second through via 462b and the fourth conductive pattern 462c may be formed in the stack region SR. Each of the first through via 462a and the second through via 462b may pass through the second anti-reflection layer 150B. For example, a first through trench T2a and a second through trench T2b may be formed in the first substrate 100 and the second anti-reflection layer 150B of the stack region SR. The first through via 462a may be formed in the first through trench T2a, and the second through via 462b may be formed in the second through trench T2b. The fourth conductive pattern 462c may be extended along the upper surface of the second anti-reflection layer 150B. The fourth conductive pattern 462c may electrically connect the first through via 462a with the second through via 462b.

The first through via 462a, the second through via 462b and the fourth conductive pattern 462c may electrically connect the first wiring structure 140 with the second wiring structure 240. For example, the first through via 462a may be connected to the first wiring 145 by passing through the first substrate 100 and the first inter-wiring insulating layer 142, and the second through via 462b may be connected to the second wiring 245 by passing through the first substrate 100 and the first inter-wiring insulating layer 142. The fourth conductive pattern 462c may connect the first wiring 145 with the second wiring 245 by connecting the first through via 462a with the second through via 462b.

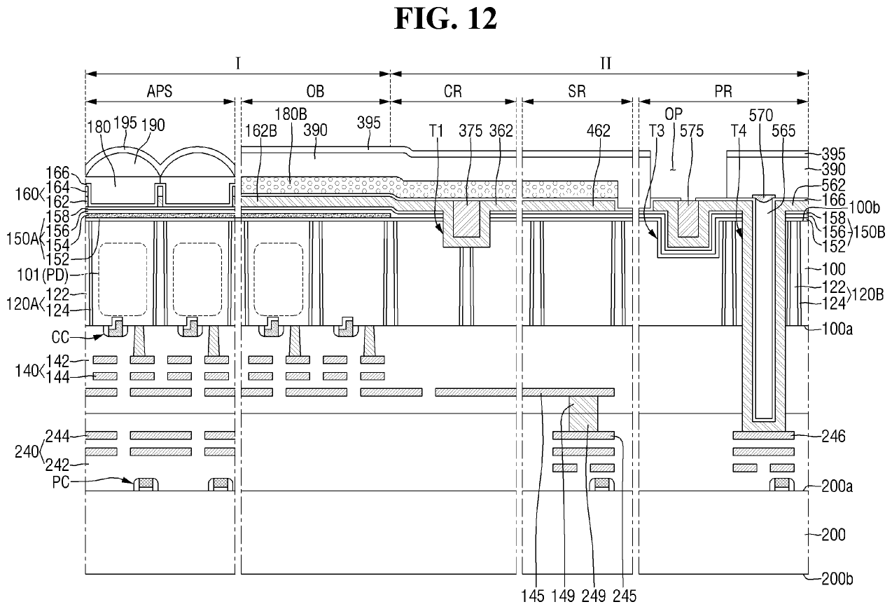

Referring to FIG. 12, the image sensor according to some embodiments includes a first bonding pattern 149 and a second bonding pattern 249.

The first bonding pattern 149 may be formed in the first inter-wiring insulating layer 142 of the stack region SR, and the second bonding pattern 249 may be formed in the second inter-wiring insulating layer 242 of the stack region SR. The first bonding pattern 149 and the second bonding pattern 249 may be electrically connected to each other.

The first bonding pattern 149 and the second bonding pattern 249 may electrically connect the first wiring structure 140 with the second wiring structure 240 in a bonding manner. The bonding manner may be, for example, a manner of electrically connecting the first bonding pattern 149 formed on the uppermost metal layer of the first wiring structure 140 with the second bonding pattern 249 formed on the uppermost metal layer of the second wiring structure 240. For example, when the first bonding pattern 149 and the second bonding pattern 249 are formed of copper (Cu), the bonding manner may be a Cu—Cu bonding manner, but this is only an example. The first bonding pattern 149 and the second bonding pattern 249 may be formed of various other metals such as aluminum (Al) or tungsten (W).

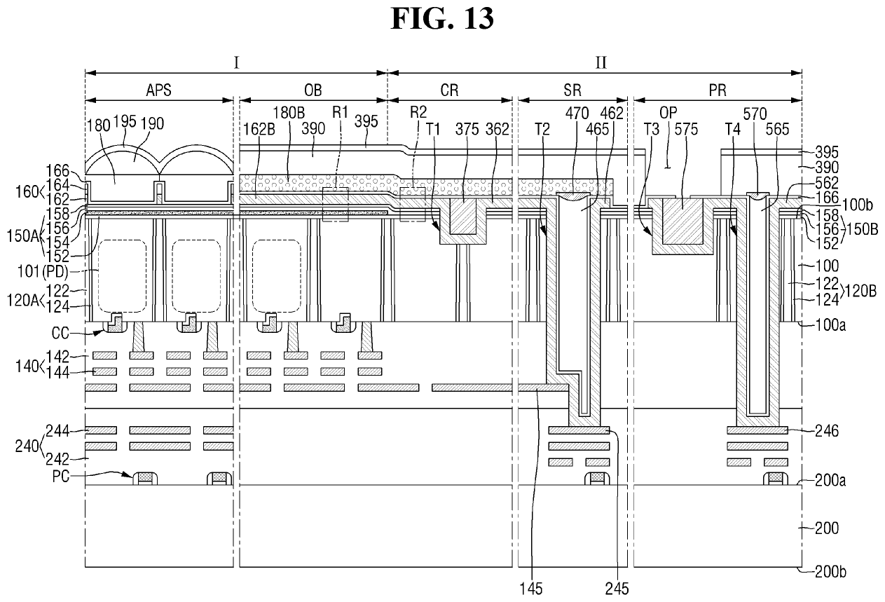

Referring to FIG. 13, in the image sensor according to some embodiments, the third trench T3 may be formed in the first substrate 100 and the second anti-reflection layer 150B.

For example, the second anti-reflection layer 150B may not be extended along the third trench T3. At least a portion of the third conductive pattern 562 may be extended to be conformal along the profile of the third trench T3 and the fourth trench T4. The pad pattern 575 may fill the third trench T3 on the third conductive pattern 562.

Hereinafter, a method for fabricating an image sensor according to example embodiments will be described with reference to FIGS. 1 to 24.

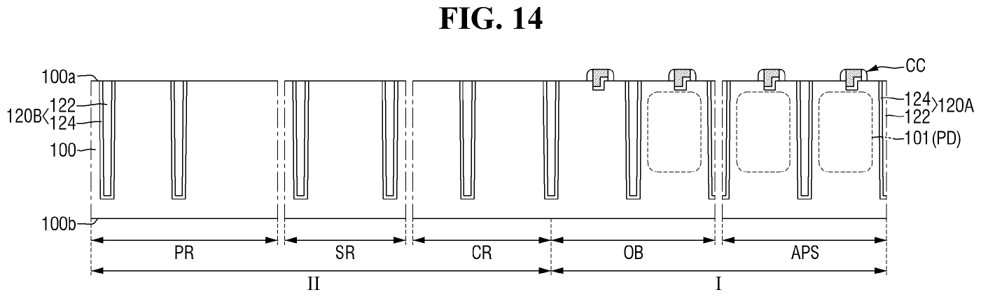

FIGS. 14 to 22 are views illustrating intermediate steps to describe a method for fabricating an image sensor according to some embodiments. For convenience of description, portions duplicated with those described with reference to FIGS. 1 to 13 will be briefly described or omitted.

Referring to FIG. 14, the photoelectric conversion region 101, the first element isolation pattern 120A and the second element isolation pattern 120B are formed in the first substrate 100.

The first substrate 100 may include the first surface 100a and the second surface 100b, which are opposite to each other. The photoelectric conversion region 101 may be formed in the first substrate 100. For example, the photoelectric conversion region 101 may be formed by ion implantation of n-type impurities into the p-type first substrate 100. The first element isolation pattern 120A and the second element isolation pattern 120B may be formed by burying an insulating material in a deep trench formed by patterning the first substrate 100.

Subsequently, the first circuit element CC may be formed on the first substrate 100. The first circuit element CC may be formed on the first surface 100a of the first substrate 100.

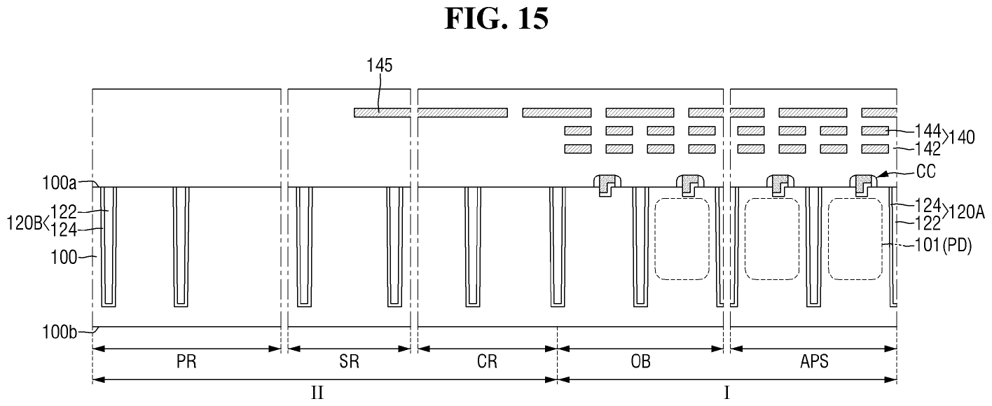

Referring to FIG. 15, the first wiring structure 140 is formed on the first substrate 100.

The first wiring structure 140 may be formed on the first surface 100a of the first substrate 100. The first wiring structure 140 may include a plurality of wiring patterns. For example, the first wiring structure 140 may include the first inter-wiring insulating layer 142 and the first wiring pattern 144.

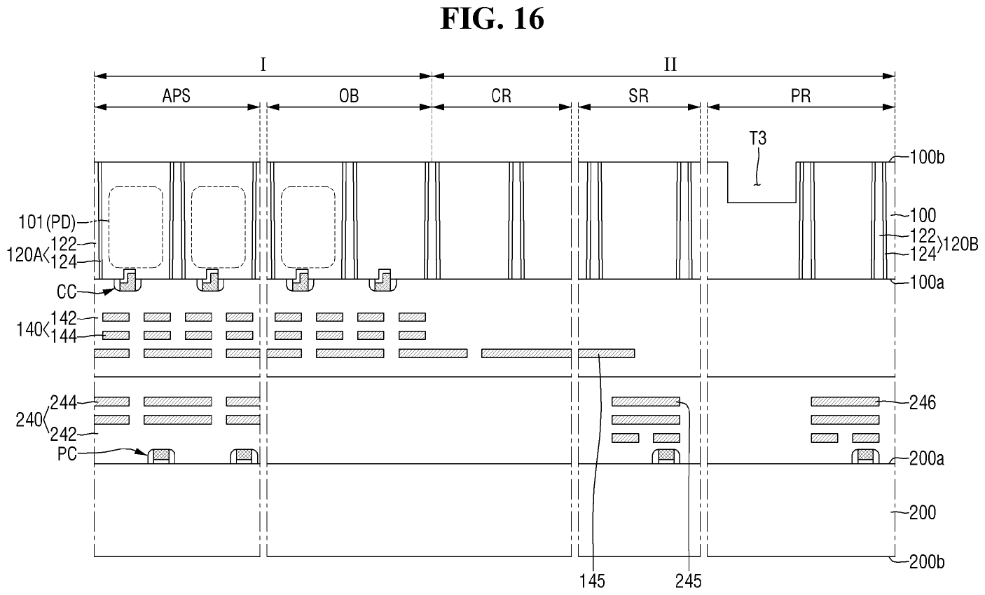

Referring to FIG. 16, the first substrate 100 and the first wiring structure 140 are stacked on the second substrate 200 and the second wiring structure 240.

The first surface 100a of the first substrate 100 may be stacked to face the third surface 200a of the second substrate 200. For example, the lower surface of the first wiring structure 140 may be attached onto the upper surface of the second wiring structure 240. The first wiring structure 140 and the second wiring structure 240 may be bonded to each other by, for example, a wafer bonding process, but are not limited thereto.

In some embodiments, a thinning process for the second surface 100b of the first substrate 100 may be performed. For example, a back grinding process for the second surface 100b of the first substrate 100 may be performed. As the thinning process is performed, the thickness of the first substrate 100 may be reduced so that the first element isolation pattern 120A and the second element isolation pattern 120B may be exposed from the second surface 100b.

In some embodiments, the third trench T3 may be formed in the first substrate 100 of the pad region PR. The third trench T3 may be formed by patterning the first substrate 100 including the second surface 100b.

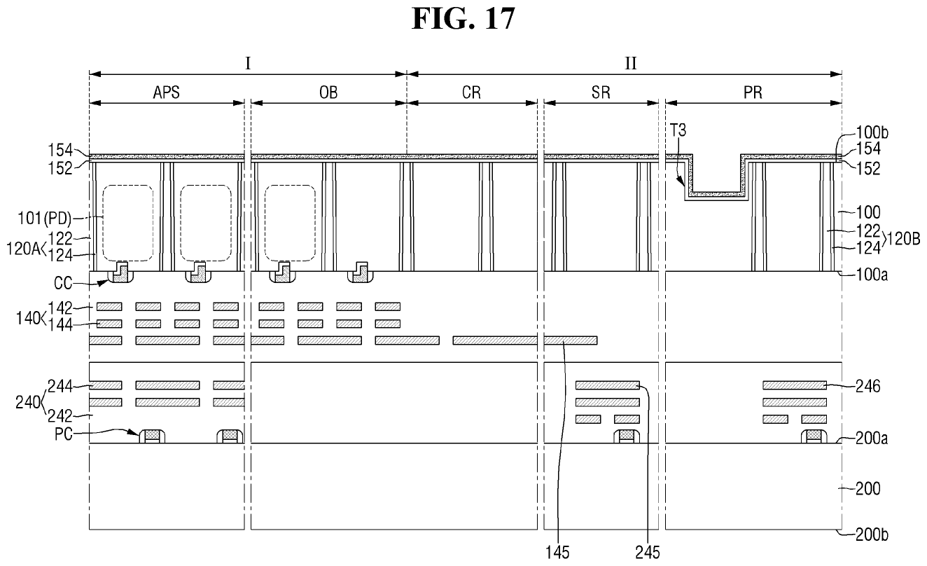

Referring to FIG. 17, the first insulating material layer 152 and the conductive material layer 154 are formed on the second surface 100b of the first substrate 100.

The first insulating material layer 152 and the conductive material layer 154 may be sequentially stacked on the second surface 100b of the first substrate 100. The first insulating material layer 152 and the conductive material layer 154 may be extended over the first region I and the second region II, respectively.

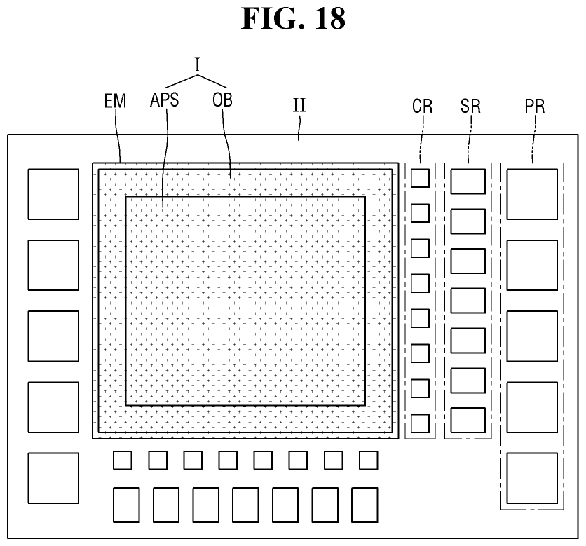

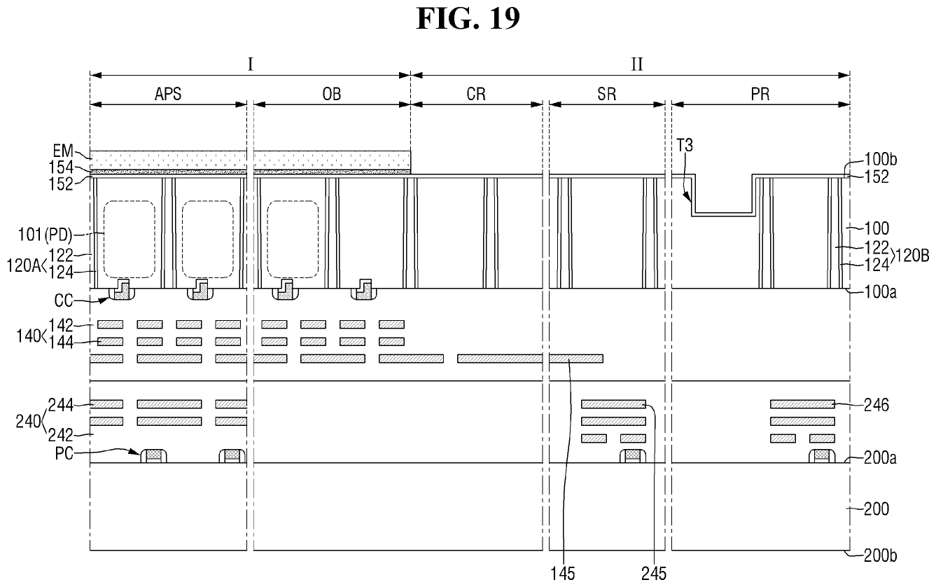

Referring to FIGS. 18 and 19, the conductive material layer 154 of the second region II is removed.

For example, a mask pattern EM may be formed on the conductive material layer 154 of the first region I. Subsequently, an etching process using the mask pattern EM as an etch mask may be performed. Therefore, the conductive material layer 154 of the first region I may remain, and the conductive material layer 154 of the second region II may be removed.

In some embodiments, the first insulating material layer 152 of the second region II may not be etched or only a portion thereof may be etched by the etching process. Therefore, the first insulating material layer 152 may remain over the first region I and the second region II. In addition, the thickness of the first insulating material layer 152 of the first region I may be equal to or smaller than that of the second insulating material layer 156 of the second region II.

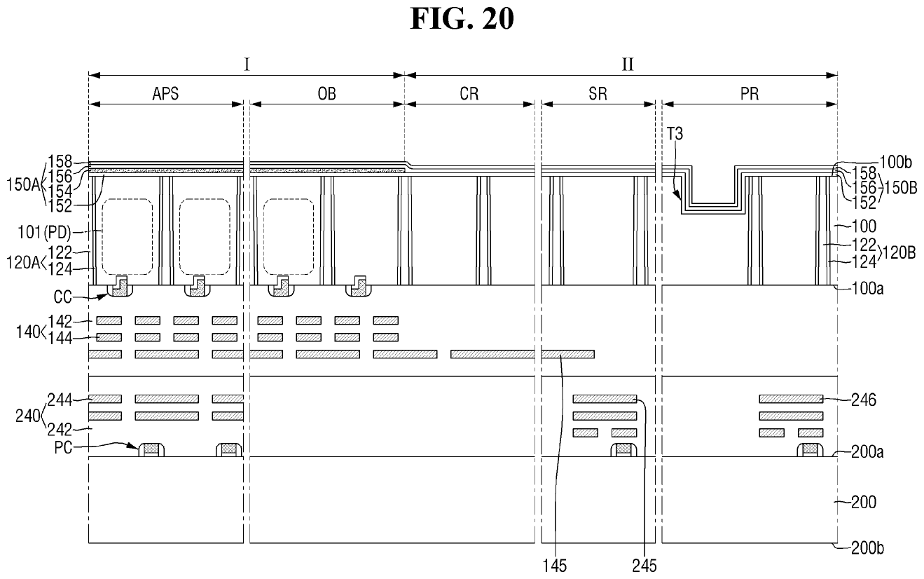

Referring to FIG. 20, the second insulating material layer 156 and the third insulating material layer 158 are formed on the conductive material layer 154 and the first insulating material layer 152.

The second insulating material layer 156 and the third insulating material layer 158 may be sequentially stacked on the conductive material layer 154 of the first region I and the first insulating material layer 152 of the second region II. The second insulating material layer 156 and the third insulating material layer 158 may be extended over the first region I and the second region II, respectively. Therefore, the first anti-reflection layer 150A including the first insulating material layer 152, the conductive material layer 154, the second insulating material layer 156 and the third insulating material layer 158 may be formed on the first substrate 100 of the first region I. In addition, the second anti-reflection layer 150B including the first insulating material layer 152, the second insulating material layer 156 and the third insulating material layer 158 may be formed on the first substrate 100 of the second region II.

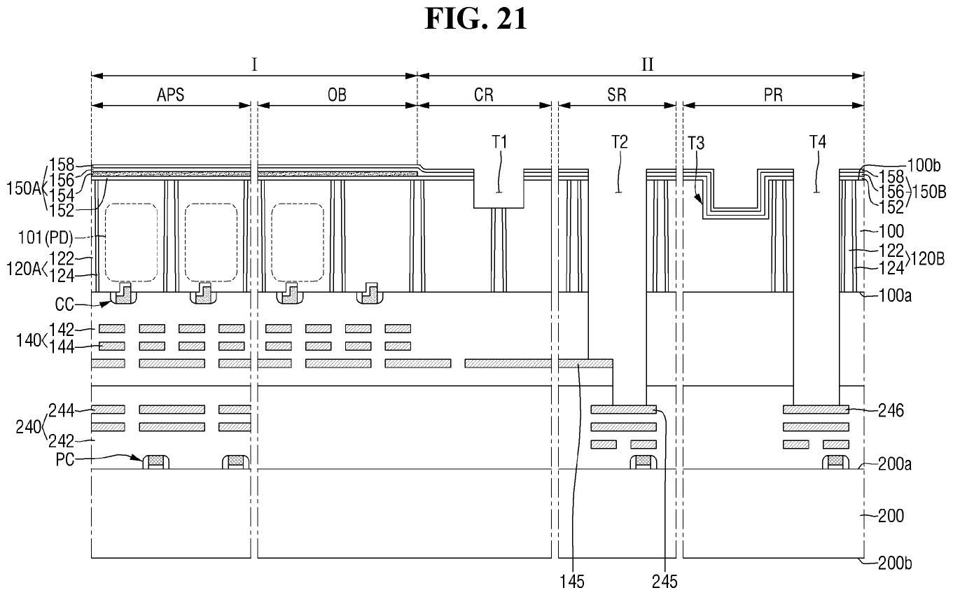

Referring to FIG. 21, the first trench T1, the second trench T2 and the fourth trench T4 are formed in the second region II.

The first trench T1 may pass through the second anti-reflection layer 150B of the contact region CR. In addition, the first trench T1 may expose the filling pattern 122 of the first element isolation pattern 120A.

The second trench T2 may pass through the second anti-reflection layer 150B of the stack region SR. In addition, the second trench T2 may expose the first wiring 145 and the second wiring 245 by passing through the first substrate 100 and the first inter-wiring insulating layer 142.

The fourth trench T4 may pass through the second anti-reflection layer 150B of the pad region PR. In addition, the fourth trench T4 may expose the third wiring 246 by passing through the first substrate 100 and the first inter-wiring insulating layer 142.

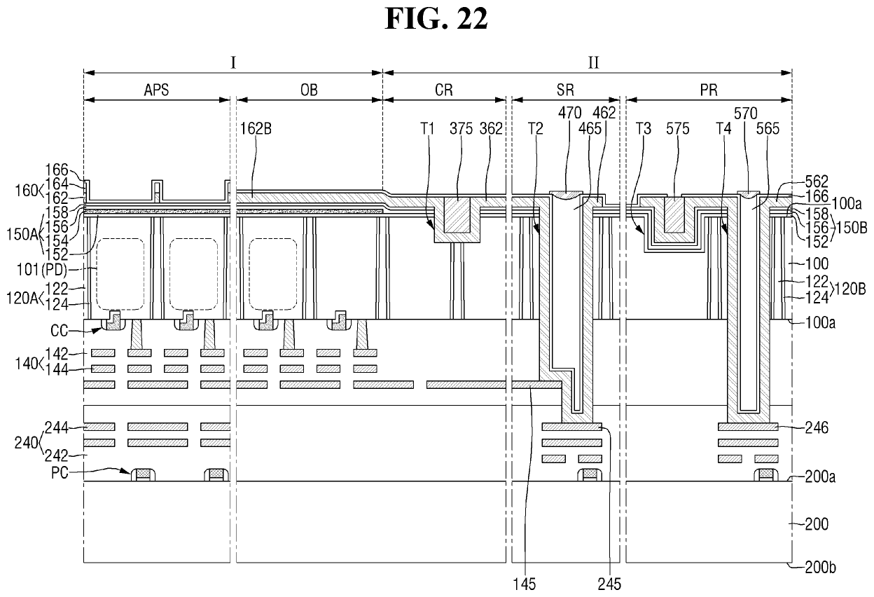

Referring to FIG. 22, the grid pattern 160, the light-blocking pattern 162B, the first conductive pattern 362, the second conductive pattern 462 and the third conductive pattern 562 are formed.

The light-blocking pattern 162B may be formed on the first anti-reflection layer 150A of the light-receiving region APS. The grid pattern 160 may overlap at least a portion of the first element isolation pattern 120A in the vertical direction.

The light-blocking pattern 162B may be formed on the first anti-reflection layer 150A of the light-blocking region OB. The light-blocking pattern 162B may cover at least a portion of the first anti-reflection layer 150A of the light-blocking region OB.

The first conductive pattern 362 may be formed on the second anti-reflection layer 150B of the contact region CR. At least a portion of the first conductive pattern 362 may be extended along the first trench T1. Therefore, the first conductive pattern 362 may be electrically connected to the filling pattern 122 of the first element isolation pattern 120A. In some embodiments, the contact pattern 375 for filling the first trench T1 may be formed on the first conductive pattern 362.

The second conductive pattern 462 may be formed on the second anti-reflection layer 150B of the stack region SR. At least a portion of the second conductive pattern 462 may be extended along the second trench T2. Therefore, the second conductive pattern 462 may electrically connect the first wiring structure 140 with the second wiring structure 240.

The third conductive pattern 562 may be formed on the second anti-reflection layer 150B of the pad region PR. At least a portion of the third conductive pattern 562 may be extended along the third trench T3 and the fourth trench T4. Therefore, the third conductive pattern 562 may electrically connect the image sensor with the external device. In some embodiments, the pad pattern 575 for filling the third trench T3 may be formed on the third conductive pattern 562.

Subsequently, the first passivation layer 166 may be formed on the grid pattern 160, the light-blocking pattern 162B, the first conductive pattern 362, the second conductive pattern 462 and the third conductive pattern 562. In some embodiments, the first filling insulating layer 465 and the first capping pattern 470 may be formed on the first passivation layer 166 in the second trench T2. In some embodiments, the second filling insulating layer 565 and the second capping pattern 570 may be formed on the first passivation layer 166 in the fourth trench T4.

Subsequently, referring to FIG. 4, the color filter 180, the microlens 190, the second passivation layer 195, the light-blocking filter 180B, the planarization layer 390 and the third passivation layer 395 are formed on the first passivation layer 166. Therefore, the image sensor described with reference to FIGS. 3 to 6 may be fabricated.

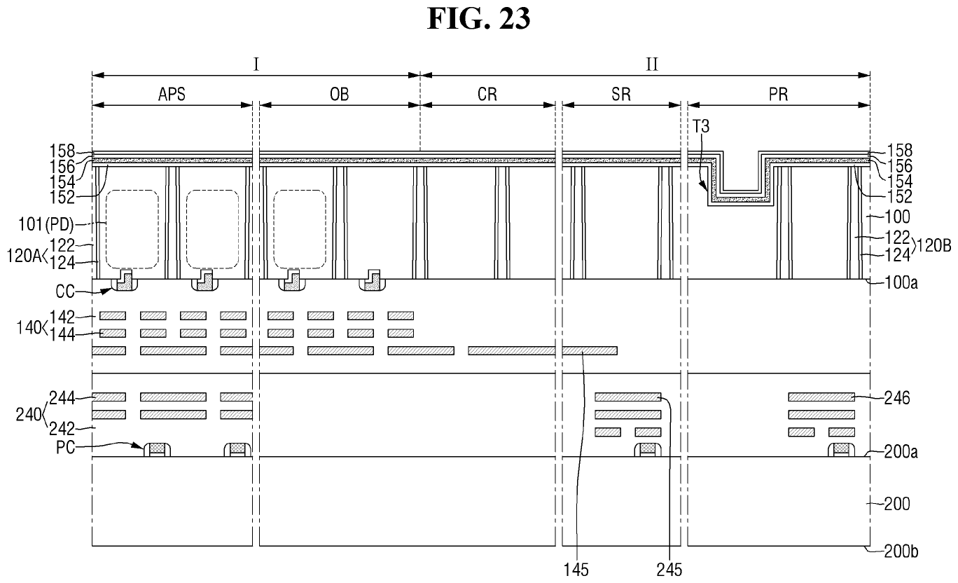

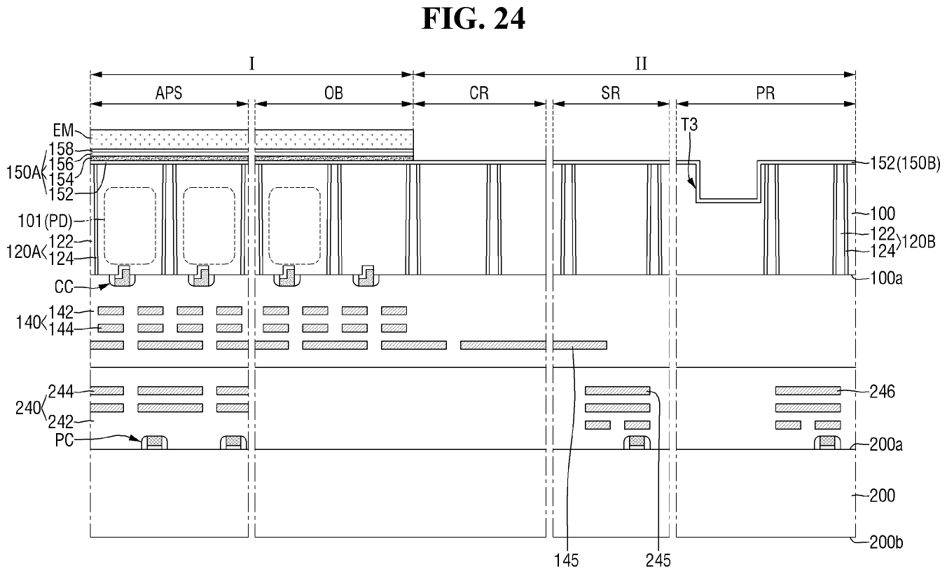

FIGS. 23 and 24 are views illustrating intermediate steps to describe a method for fabricating an image sensor according to some embodiments. For convenience of description, portions duplicated with those described with reference to FIGS. 1 to 22 will be briefly described or omitted. For reference, FIG. 23 is a view illustrating intermediate steps to describe steps subsequent to FIG. 17.

Referring to FIG. 23, the second insulating material layer 156 and the third insulating material layer 158 are formed on the conductive material layer 154. Since the formation of the second insulating material layer 156 and the third insulating material layer 158 is similar to that described with reference to FIG. 20, a detailed description thereof will be omitted.

Referring to FIG. 24, the conductive material layer 154, the second insulating material layer 156 and the third insulating material layer 158 of the second region II are removed.

For example, the mask pattern EM may be formed on the third insulating material layer 158 of the first region I. Subsequently, an etching process using the mask pattern EM as an etch mask may be performed. Therefore, the conductive material layer 154 of the first region I may remain, and the conductive material layer 154 of the second region II may be removed.

In some embodiments, the first insulating material layer 152 of the second region II may not be etched or only a portion thereof may be etched by the etching process. Therefore, the first insulating material layer 152 may remain over the first region I and the second region II. In addition, the thickness of the first insulating material layer 152 of the first region I may be equal to or smaller than that of the second insulating material layer 156 of the second region II.

Subsequently, the steps described with reference to FIGS. 21, 22 and 4 may be performed. Therefore, the image sensor described with reference to FIGS. 7 to 9 may be fabricated.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. An image sensor including a first region and a second region in the periphery of the first region, the image sensor comprising:
a substrate including a light-receiving surface on which light is incident;
a photoelectric conversion region in the substrate within the first region;
a first anti-reflection layer extended along the light-receiving surface within the first region, the first anti-reflection layer including a conductive material layer;
a second anti-reflection layer extended along the light-receiving surface within the second region, the second anti-reflection layer not including the conductive material layer; and
a conductive pattern within the second region,
wherein at least a first portion of the conductive pattern is disposed on the second anti-reflection layer and a second portion of the conductive pattern passes through the second anti-reflection layer.

2. The image sensor of claim 1, wherein a thickness of the second anti-reflection layer is smaller than a thickness of the first anti-reflection layer.

3. The image sensor of claim 1, wherein the first anti-reflection layer further includes a first insulating material layer interposed between the substrate and the conductive material layer, and
the second anti-reflection layer includes the first insulating material layer.

4. The image sensor of claim 3, wherein a thickness of the first insulating material layer of the second anti-reflection layer is equal to or smaller than a thickness of the first insulating material layer of the first anti-reflection layer.

5. The image sensor of claim 1, wherein the first anti-reflection layer further includes a second insulating material layer stacked on the conductive material layer, and
the second anti-reflection layer includes the second insulating material layer.

6. The image sensor of claim 5, wherein a thickness of the second insulating material layer of the first anti-reflection layer and a thickness of the second insulating material layer of the second anti-reflection layer are the same as each other.

7. The image sensor of claim 1, wherein the second region surrounds the periphery of the first region.

8. The image sensor of claim 1, wherein the first region includes a light-receiving region for receiving the light and a light-blocking region, which blocks the light, in the periphery of the light-receiving region.

9. An image sensor including a first region and a second region in the periphery of the first region, the image sensor comprising:
a substrate;
a photoelectric conversion region in the substrate within the first region;
a first anti-reflection layer including a first insulating material layer, a conductive material layer and a second insulating material layer, which are sequentially stacked on the substrate within the first region;
a second anti-reflection layer, which includes the first insulating material layer and the second insulating material layer that is in contact with the first insulating material layer, on the substrate within the second region; and
a conductive pattern within the second region,
wherein at least a first portion of the conductive pattern is disposed on the second anti-reflection layer and a second portion of the conductive pattern passes through the second anti-reflection layer.

10. The image sensor of claim 9, wherein a thickness of the first insulating material layer of the second anti-reflection layer is equal to or smaller than a thickness of the first insulating material layer of the first anti-reflection layer.

11. The image sensor of claim 9, wherein a thickness of the second insulating material layer of the first anti-reflection layer and a thickness of the second insulating material layer of the second anti-reflection layer are the same as each other.

12. The image sensor of claim 9, wherein the first insulating material layer includes aluminum oxide (AlO).

13. The image sensor of claim 9, wherein the conductive material layer includes titanium oxide (TiO).

14. An image sensor including a first region and a second region in the periphery of the first region, the image sensor comprising:
a first substrate including a first surface and a second surface, which are opposite to each other;
a photoelectric conversion region in the first substrate within the first region;
a first circuit element on the first surface of the first substrate;
a first wiring structure, which is electrically connected to the first circuit element, on the first surface of the first substrate;
a first anti-reflection layer, which includes at least one insulating material layer and at least one conductive material layer, on the second surface of the first substrate within the first region;
a second anti-reflection layer, which includes the at least one insulating material layer and does not include the at least one conductive material layer, on the second surface of the first substrate within the second region;
a conductive pattern within the second region, at least a first portion of the conductive pattern is disposed on the second anti-reflection layer and a second portion of the conductive pattern passes through the second anti-reflection layer;
a second substrate including a third surface facing the first surface of the first substrate and a fourth surface opposite to the third surface;
a second circuit element on the third surface of the second substrate; and
a second wiring structure, which is electrically connected to the second circuit element, on the third surface of the second substrate.

15. The image sensor of claim 14, wherein the first region includes a light-receiving region for receiving the light, and a light-blocking region, which blocks the light, in the periphery of the light-receiving region.

16. The image sensor of claim 15, further comprising:
a color filter on the first anti-reflection layer within the light-receiving region;
a microlens on the color filter; and
a light-blocking pattern on the first anti-reflection layer within the light-blocking region.

17. The image sensor of claim 14, further comprising an element isolation pattern, which defines a plurality of unit pixels, in the substrate within the first region,
wherein the photoelectric conversion region is disposed in each of the unit pixels, and
the conductive pattern is electrically connected to the element isolation layer.

18. The image sensor of claim 14, wherein the conductive pattern is electrically connected to the second wiring structure through the first substrate.

19. The image sensor of claim 18, wherein the conductive pattern electrically connects the first wiring structure with the second wiring structure by passing through the first substrate.

20. The image sensor of claim 14, further comprising a trench, which is extended from the second surface, in the substrate,
wherein a portion of the second anti-reflection layer is extended along a profile of the trench.
